(19) United States
(12) Patent Application Publication
(10) Pub. No.: US 2026/0220938 A1
(43) Pub. Date: Jul. 30, 2026

(54) WORK ASSISTANCE METHOD AND WORK ASSISTANCE SYSTEM

(71) Applicant: SCREEN Holdings Co., Ltd., Kyoto (JP)

(72) Inventors: Shinji SHIMIZU, Kyoto-shi, Kyoto (JP); Akihiro MINOGUCHI, Kyoto-shi, Kyoto (JP)

(21) Appl. No.: 19/143,369

(22) PCT Filed: Nov. 21, 2023
(86) PCT No.: PCT/JP2023/041701

§ 371 Date: Jun. 25, 2025

(30) Foreign Application Priority Data
Dec. 28, 2022 (JP) 2022-211098

(51) Int. Cl. G06V 20/40; G06T 7/70; G08B 7/06

(52) U.S. Cl. CPC G06V 20/41; G06T 7/70; G08B 7/066

(57) ABSTRACT

A large number of substrate processing apparatuses are disposed side by side in a clean room. As previous preparation processing, positions of the plurality of substrate processing apparatuses in the clean room are recorded based on a taken image obtained by taking an image of the plurality of substrate processing apparatuses disposed in the clean room. When abnormality is detected in any of the plurality of substrate processing apparatuses, a smart glass displays coping information for coping with the abnormality. When a value of an abnormality level is equal to or larger than a predetermined threshold value, the smart glass determines and displays an evacuation route for evacuation of a worker. Accordingly, even when the abnormality occurs in the substrate processing apparatus, the worker in the clean room can easily recognize a coping method.

### TECHNICAL FIELD

The present invention relates to a work assistance method and a work assistance system performing assistance to cope with abnormality when abnormality occurs in a substrate processing apparatus performing predetermined processing such as cleaning processing on a substrate. Examples of a substrate to be processed by the substrate processing apparatus include a semiconductor substrate, a liquid crystal display apparatus substrate, a flat panel display (FPD) substate, an optical disk substrate, a magnetic disk substrate, or a solar cell substrate.

### BACKGROUND ART

A substrate processing apparatus performing various types of processing on a substate such as a semiconductor substrate is conventionally used in a process of manufacturing a semiconductor device. A substrate cleaning apparatus, a heat treatment apparatus, and an inspection apparatus, for example, are used as the substrate processing apparatus. Typically, a number of substrate processing apparatuses are systematically disposed in a large clean room in many cases. For example, Patent Document 1 describes that a number of substrate processing apparatuses are disposed in a clean room to be arranged at a relatively high density in a manufacturing plant of a semiconductor device.

Generally, a worker performs an operation work on any substrate processing apparatus in the clean room. The worker enters inside the substrate processing apparatus and performs a confirmation work.

### PRIOR ART DOCUMENTS

### Patent Document(s)

Patent Document 1: Japanese Patent Application Laid-Open No. 2020-4866

### SUMMARY

### Problem to be Solved by the Invention

Various types of abnormality occur in processing and an alarm is generated in the substrate processing apparatus in some cases. For example, abnormality such as leakage of a processing solution or processing gas, collision of a robot, and a crack of a substrate may occur. When high-risk abnormality occurs in the substrate processing apparatus, a worker needs to immediately evacuate to a safe position.

However, when the alarm is generated, it is difficult for the worker to immediately grasp what kind of abnormality occurs in the substrate processing apparatus. Also when a high-risk alarm is generated, a coping method such as an evacuation method is previously determined in a procedure document, for example. However, the worker cannot rapidly determine how to cope with the abnormality in a large clean room in many cases.

When abnormality occurs in the substrate processing apparatus when the worker is located inside the substrate processing apparatus, the worker should immediately get out of the substrate processing apparatus.

However, when the worker hastily moves inside the substrate processing apparatus, the worker may collide with a robot inside the apparatus and get into risk.

The present invention is therefore has been made to solve the above problems, and it is a first object to provide a work assistance technique enabling a worker in a clean room to easily recognize a coping method when abnormality occurs in a substrate processing apparatus.

A second object of the present invention is to provide a work assistance technique enabling a worker in a substrate processing apparatus to safely get out of the apparatus when abnormality occurs in the substrate processing apparatus.

### Means to Solve the Problem

In order to achieve the first object described above, a first aspect of the present invention is a work assistance method in occurrence of abnormality in a substrate processing apparatus performing predetermined processing on a substrate, including: an imaging step of taking an image of a plurality of substrate processing apparatuses disposed in a clean room by a mobile terminal including an imaging part and a communication part; a device position recording step of recording positions of the plurality of substrate processing apparatuses in the clean room base on an taken image obtained in the imaging step; and a displaying step of displaying coping information for coping with abnormality on the mobile terminal when the abnormality is detected in any of the plurality of substrate processing apparatuses.

A second aspect is the work assistance method according to the first aspect, further comprising: an evacuation position recording step of recording an evacuation position in the clean room; and a position detection step of detecting a position of the mobile terminal based on an image taken by the mobile terminal when the abnormality is detected, wherein in the displaying step, an evacuation route from the position of the mobile terminal detected in the position detection step to the evacuation position is specified and is displayed.

A third aspect is the work assistance method according to the second aspect, wherein in the imaging step and the position detection step, the image taken by the mobile terminal is scanned and converted into a form of a spatial mesh.

A fourth aspect is the work assistance method according to any one of the first to third aspects, wherein the mobile terminal is a smart glass.

In order to achieve the second object described above, a fifth aspect of the present invention is a work assistance method in occurrence of abnormality in a substrate processing apparatus performing predetermined processing on a substrate, including: a specifying step of specifying a state of a processing part included in a substrate processing apparatus when abnormality of the substrate processing apparatus is detected during a work in the substrate processing apparatus; and a displaying step of displaying information for evacuating from the substrate processing apparatus on a mobile terminal including an imaging part and a communication part based on the state of the processing part specified in the specifying step.

A sixth aspect is the work assistance method according to the fifth aspect, further comprising a recording step of obtaining and recording three-dimensional design information regarding at least a driving part in a processing part included in the substrate processing apparatus, wherein in the specifying step, a posture of the driving part is specified based on the three-dimensional design information and an image of the driving part taken by the mobile terminal when abnormality occurs, and in the displaying step, the information for evacuating from the substrate processing apparatus is displayed based on the posture of the driving part specified in the specifying step.

A seventh aspect is the work assistance method according to the fifth or sixth aspect, wherein the mobile terminal is a smart glass.

In order to achieve the first object described above, an eighth aspect of the present invention is a work assistance system in occurrence of abnormality in a substrate processing apparatus performing predetermined processing on a substrate, including: a plurality of substrate processing apparatuses disposed in a clean room; a mobile terminal including an imaging part and a communication part; a position recording part recording positions of the plurality of substrate processing apparatuses in the clean room and an evacuation position in the clean room based on a taken image obtained by taking an image of the plurality of substrate processing apparatuses by the mobile terminal; and an abnormality processing part detecting a position of the mobile terminal based on an image taken by the mobile terminal when abnormality is detected in any of the plurality of substrate processing apparatuses, specifying an evacuation route from the position of the mobile terminal to the evacuation position, and displaying the evacuation route on the mobile terminal.

A ninth aspect is the work assistance system according to the eighth aspect, wherein the mobile terminal is a smart glass.

In order to achieve the second object described above, a tenth aspect of the present invention is a work assistance system in occurrence of abnormality in a substrate processing apparatus performing predetermined processing on a substrate, comprising: a substrate processing apparatus disposed in a clean room; a mobile terminal including an imaging part and a communication part; a storage part storing three-dimensional design information regarding at least a driving part in a processing part included in the substrate processing apparatus; a posture specifying part specifying a posture of the driving part based on the three-dimensional design information and an image of the driving part taken by the mobile terminal when abnormality of a substrate processing apparatus is detected during a work in the substrate processing apparatus; and an abnormality processing part displaying information for evacuating from the substrate processing apparatus on the mobile terminal based on the posture of the driving part specified by the posture specifying part.

An eleventh aspect is the work assistance system according to the tenth aspect, wherein the mobile terminal is a smart glass.

### Effects of the Invention

According to the work assistance method according to the first to fourth aspects, when abnormality is detected in any of the plurality of substrate processing apparatuses, coping information for coping with the abnormality is displayed on the mobile terminal. Thus, when the abnormality occurs in the substrate processing apparatus, the worker having the mobile terminal in the clean room can easily recognize a coping method.

Particularly, according to the work assistance method in the second aspect, the evacuation route from the position of the mobile terminal to the evacuation position is displayed. Thus, the worker can easily recognize the evacuation route.

According to the work assistance method in the fifth to seventh aspects, when abnormality of the substrate processing apparatus is detected during a work in the substrate processing apparatus, the information for evacuating from the substrate processing apparatus is displayed on the mobile terminal based on the state of the processing part included in the substrate processing apparatus. Thus, when the abnormality occurs in the substrate processing apparatus, the worker in the substrate processing apparatus can safely get out of the apparatus.

Particularly, according to the work assistance method in the sixth aspect, the posture of the driving part is specified based on the three-dimensional design information and the image of the driving part taken by the mobile terminal when the abnormality occurs, and the information for evacuating from the substrate processing apparatus is displayed based on the posture of the driving part. Thus, the worker can safely get out of the apparatus while being away from the driving part.

According to the work assistance system in the eighth and ninth aspects, when the abnormality is detected in any of the plurality of substrate processing apparatuses, the position of the mobile terminal is detected based on the image taken by the mobile terminal, and the evacuation route from the position of the mobile terminal to the evacuation position is specified and displayed on the mobile terminal. Thus, the worker having the mobile terminal in the clean room can easily recognize the coping method when the abnormality occurs in the substrate processing apparatus.

According to the work assistance system in the tenth and eleventh aspects, when the abnormality of the substrate processing apparatus is detected during the work in the substrate processing apparatus, the posture of the driving part is specified based on the three-dimensional design information regarding the drive part and the image of the driving part taken by the mobile terminal, and the information for evacuating from the substrate processing apparatus is displayed on the mobile terminal based on the posture of the driving part. Thus, when the abnormality occurs in the substrate processing apparatus, the worker in the substrate processing apparatus can safely get out of the apparatus.

### BRIEF DESCRIPTION OF DRAWINGS

FIG. 1 is a diagram schematically illustrating a schematic configuration of a work assistance system according to the present invention.

FIG. 2 is a plan view illustrating an example of a layout of a plurality of substrate processing apparatuses.

FIG. 3 is a side view illustrating an example of an arrangement of the plurality of substrate processing apparatuses.

FIG. 4 is a side view illustrating a configuration of one substrate processing apparatus.

FIG. 5 is a plan view of the substrate processing apparatus.

FIG. 6 is a diagram illustrating a schematic configuration of a processing unit.

FIG. 7 is a perspective view illustrating an appearance of a smart glass.

FIG. 8 is a block diagram illustrating a functional configuration of a smart glass, a server, and a work assistance terminal.

FIG. 9 is a flow chart illustrating a procedure of a work assistance method according to the present invention.

FIG. 10 is a flow chart illustrating a procedure of the work assistance method according to the present invention.

FIG. 11 is a diagram illustrating an example of an taken image converted into a form of a spatial mesh.

FIG. 12 is a diagram schematically illustrating a relative positional relationship between a reference position and the substrate processing apparatus.

FIG. 13 is a diagram illustrating an example of display of an evacuation route. FIG. 14 is a flow chart illustrating a procedure of a work assistance method according to a second embodiment.

FIG. 15 is a flow chart illustrating a procedure of the work assistance method according to the second embodiment.

FIG. 16 is a diagram illustrating an image of a driving part taken by a smart glass.

FIG. 17 is a diagram illustrating a posture of the driving part specified by a smart glass.

### DESCRIPTION OF EMBODIMENT(S)

Embodiments according to the present invention will now be described in detail with reference to the diagrams. In the description hereinafter, unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “uniform”) include those indicating quantitatively exact equality and those in the presence of a difference within tolerance or to the extent that similar functions can be obtained. Unless otherwise noted, the expressions indicating shapes (e.g., “circular”, “rectangular”, and “cylindrical”) include those indicating geometrically exact shapes and those indicating, for example, roughness or a chamfer to the extent that similar effect can be obtained. An expression “comprising”, “including”, or “having” a certain constituent element is not an exclusive expression for excluding the presence of the other constituent elements. An expression “at least one of A, B, and C” involves “only A”, “only B”, “only C”, “arbitrary two of A, B, and C”, and “all of A, B, and C”.

### First Embodiment

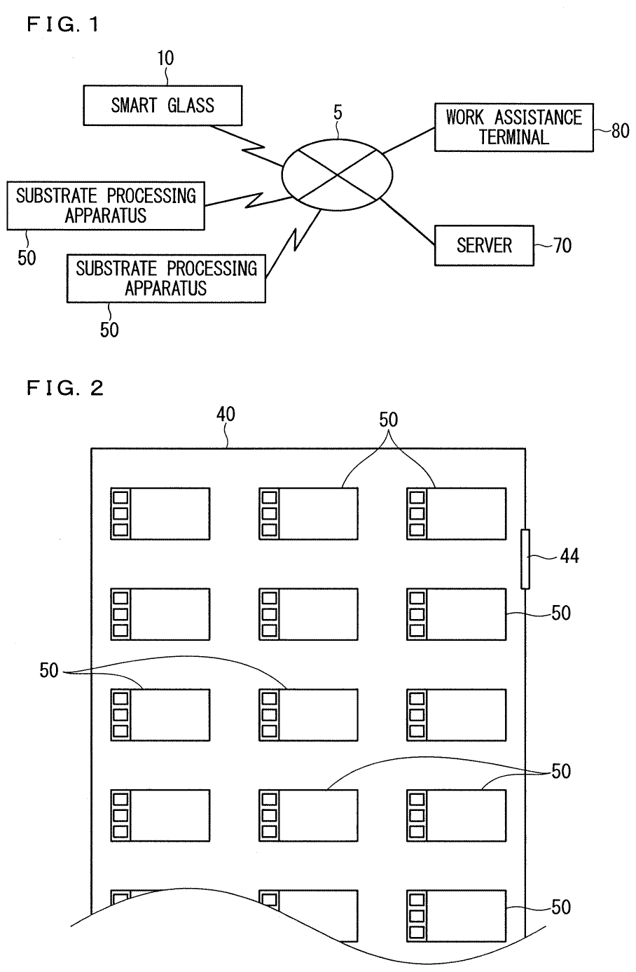

FIG. 1 is a diagram schematically illustrating a schematic configuration of a work assistance system according to the present invention. The work assistance system according to the present invention includes a plurality of substrate processing apparatuses 50, a smart glass 10, a server 70, and a work assistance terminal 80. Controllers of the smart glass 10 and the substrate processing apparatus 50 are connected to an information communication network 5 (for example, Internet) via wireless communication. The work assistance terminal 80 and the server 70 are connected to the information communication network 5 by wire. Information can be mutually transmitted and received between apparatuses connected to the information communication network 5, and information can be provided and received between the smart glass 10 and the work assistance terminal 80, for example. Whether each apparatus and the information communication network 5 are connected wirelessly or by wire is not limited to the above example. However, an appropriate configuration is applicable (for example, the work assistance terminal 80 and the information communication network 5 may be wirelessly connected.)

FIG. 2 is a plan view illustrating an example of a layout of the plurality of substrate processing apparatuses 50. As illustrated in FIG. 2, the plurality of substrate processing apparatuses 50 are regularly disposed side by side at regular intervals in the clean room 40. The clean room 40 is provided in a manufacturing plant of a semiconductor device, for example, and is a room in which constant air cleanliness is ensured and a temperature and humidity are managed. An evacuation port 44 is provided to the clean room 40 for emergency evacuation. In the first embodiment, the same type and the same form of the plurality of substrate processing apparatuses 50 are disposed in the relatively large clean room 40. Accordingly, it is difficult for the worker to distinguish the substrate processing apparatus 50 disposed in the clean room 40 from an appearance.

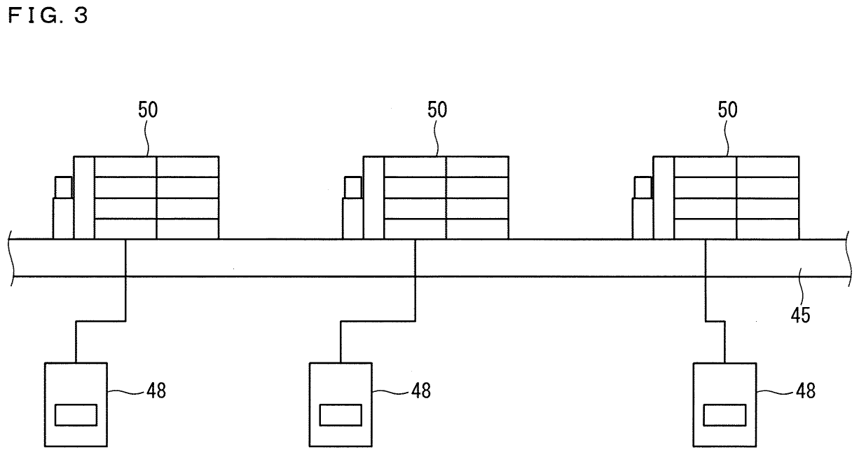

FIG. 3 is a side view illustrating an example of an arrangement of the plurality of substrate processing apparatuses 50. An accessory unit 48 is provided to the substrate processing apparatus 50 separately from a body. For example, when the substrate processing apparatus 50 is a substrate cleaning apparatus using a chemical solution, a chemical solution cabinet supplying a chemical solution to the substrate processing apparatus 50 is provided as the accessory unit. For example, when the substrate processing apparatus 50 is a heat treatment apparatus emitting light from a lamp to the substrate, a power source unit supplying electrical power to the lamp of the substrate processing apparatus 50 is provided as the accessory unit. The accessory unit 48 is provided separately from the substrate processing apparatus 50. In the present embodiment, the substrate processing apparatus 50 is disposed on a floor 45 of the clean room 40, and the accessory unit 48 is provided below the floor 45. The substrate processing apparatus 50 on the floor is connected to the corresponding accessory unit 48 below the floor by a pipe or a cable passing through the floor 45. In the present embodiment, the plurality of substrate processing apparatuses 50 and the plurality of accessory units 48 correspond to each other on a one-to-one basis.

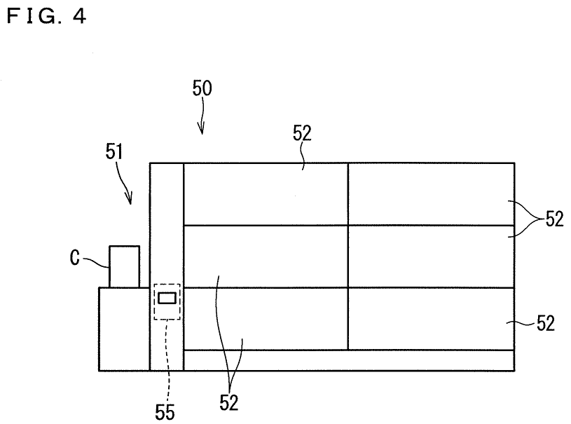

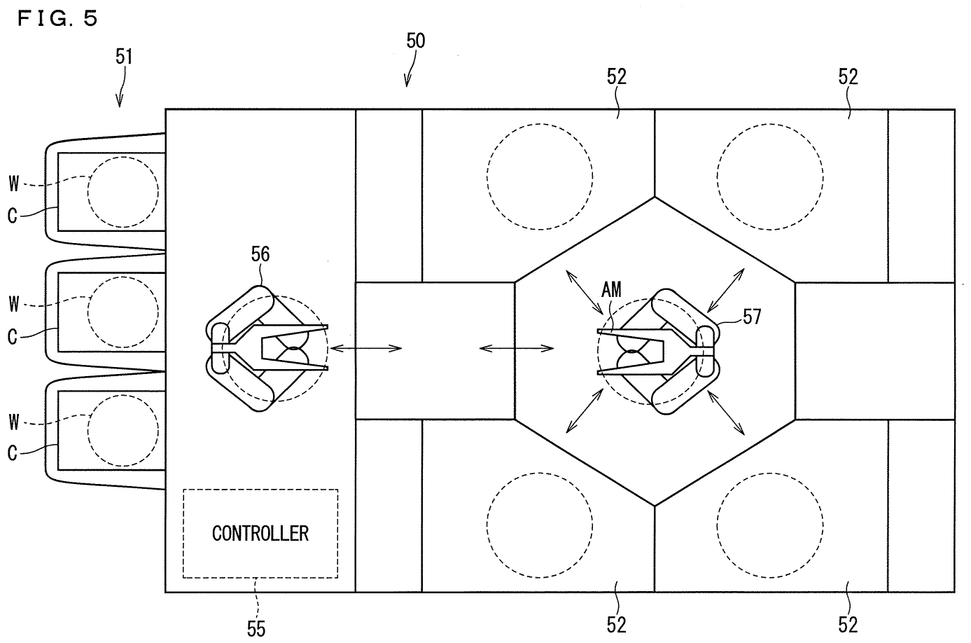

FIG. 4 is a side view illustrating a configuration of one substrate processing apparatus 50. FIG. 5 is a plan view of the substrate processing apparatus 50. In the first embodiment, the substrate processing apparatus 50 is a single wafer type substrate cleaning apparatus cleaning a substrate one by one, for example. The substrate processing apparatus 50 includes an indexer 51, a plurality of processing units 52, a transfer robot 56, and a main transport robot 57.

A carrier C housing a plurality of substrates W is disposed in the indexer 51. Three carriers C can be disposed in the indexer 51, for example. The transfer robot 56 can perform a slide movement along a direction of arrangement of the plurality of carriers C, a vertical movement, a pivot movement, and a hand advancing/retracting movement. The transfer robot 56 takes out the unprocessed substrate W from the carrier C disposed in the indexer 51. The transfer robot 56 houses the substrate W which has been processed in the carrier C disposed in the indexer 51. The carrier C is a front opening unified pod (FOUP) housing the substrate W in an enclosed space, for example.

In the first embodiment, three processing units 52 are stacked to constitute one laminated body, for example. Four laminated bodies are disposed around the main transport robot 57 of the substrate processing apparatus 50, for example. That is to say, one substrate processing apparatus 50 includes twelve (=3×4) processing units 52, for example.

The main transport robot 57 disposed in a center of the four laminated bodies can perform a vertical movement, a pivot movement, and an advancing/retracting movement of a transport arm AM. The main transport robot 57 can transport the substrate W to and from all of the twelve processing units 52. The main transport robot 57 receives the unprocessed substrate W from the transfer robot 56 and transports the unprocessed substrate W to any of the twelve processing units 52. The main transport robot 57 transports the substate W which has been processed from the processing unit 52 and passes the substate W to the transfer robot 56.

The substrate processing apparatus 50 includes a controller 55. The controller 55 is a general computer, and controls an operation of the transfer robot 56, the main transport robot 57, and each processing unit 52 described above in the apparatus. The controller 55 includes a touch panel as an input-output interface provided to a wall surface of the apparatus and a communication part having communication with an outer part of the apparatus.

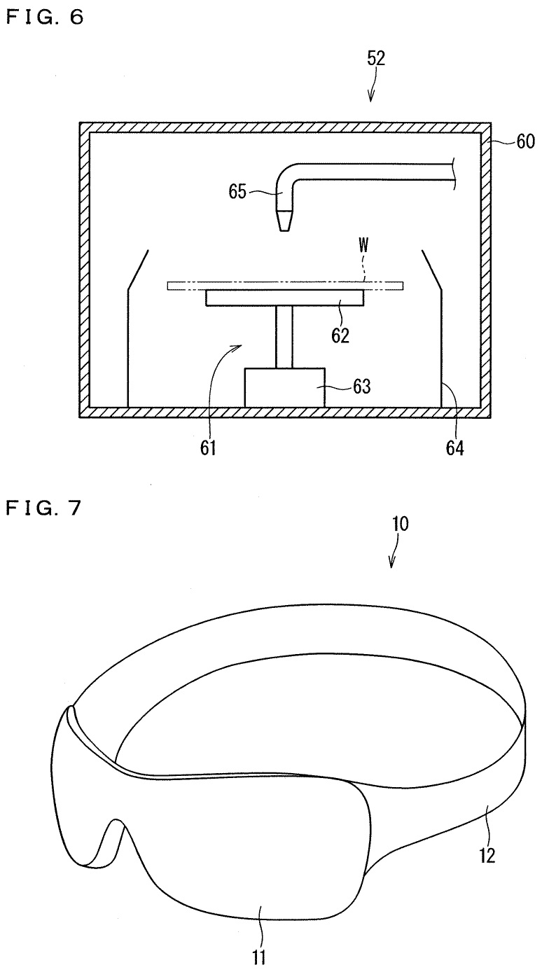

FIG. 6 is a diagram illustrating a schematic configuration of the processing unit 52. The processing unit 52 includes a processing chamber 60, a rotation holding part 61, and a discharge nozzle 65. The processing chamber 60 is a hollow housing. The rotation holding part 61 and the discharge nozzle 65 are provided inside the processing chamber 60. A transfer port not shown in the diagrams is provided to the processing chamber 60. The transfer port is opened and closed by a shutter. The main transport robot 57 transports the substrate W into and out of the processing chamber 60 while the transfer port is opened. The transfer port is closed during processing on the substrate W. An air supply mechanism and an air exhaust mechanism not shown are provided to the processing chamber 60.

The rotation holding part 61 includes a spin chuck 62 and a spin motor 63. The spin chuck 62 is a substrate holding part holding the substrate W in a horizontal posture (posture in which a normal line of a main surface of the substrate W follows a vertical direction). The spin chuck 62 is a vacuum suction chuck, for example. The spin chuck 62 sucks and holds a center part of a lower surface of the substrate W. The spin chuck 62 may be a chuck in the other form such as a grasping-type mechanical chuck.

The spin chuck 62 has a disk-like shape with a diameter smaller than the substrate W. In a state where the lower surface of the substrate W is sucked and held by the spin chuck 62, the peripheral edge part of the substrate W protrudes to an outer side than an outer surrounding end of the spin chuck 62.

The spin chuck 62 is connected to the spin motor 63 via a motor shaft. That is to say, an upper end of the motor shaft of the spin motor 63 is connected to a center part of the lower surface of the spin chuck 62. When the spin motor 63 rotates the motor shaft while the substrate W is sucked and held by the spin chuck 62, the substrate W and the spin chuck 62 are rotated in a horizontal plane around a central axis along the vertical direction.

A cup 64 is provided to surround the spin chuck 62. The cup 64 can go up and down by an elevating mechanism not shown in the diagrams. The cup 64 has a cylindrical shape, and an upper part of the cup 64 is inclined to get closer to the spin chuck 62 toward an upper side. However, an inner diameter of an upper end part of the cup 64 is larger than the diameter of the substrate W. In processing the substrate W, the upper end of the cup 64 is located in a higher position than a height position of the substrate W held by the spin chuck 62. Accordingly, a liquid flying in all directions from the substrate W rotated by the spin motor 63 by centrifugal force is received by the cup 64 and collected. The liquid collected by the cup 64 is discharged from a discharge solution pipe provided to a bottom part of the cup 64. The cup 64 may have a multi-stage structure that a plurality of collection ports are provided for various purposes.

The discharge nozzle 65 discharges a processing solution to the substrate W held by the spin chuck 62. The processing solution is a conceptual term including various types of chemical solutions and pure water. Examples of the chemical solution include a solution for performing etching processing or a solution for removing particles, and applied specifically is an SC-1 solution (a mixed solution of ammonium hydroxide, hydrogen peroxide water, and pure water), an SC-2 solution (a mixed solution of hydrochloric acid, hydrogen peroxide water, and pure water), or hydrofluoric acid, for example. The discharge nozzle 65 is moved between a processing position above the spin chuck 62 and a standby position outside the cup 64 by a drive mechanism not shown in the diagrams. When the discharge nozzle 65 discharges the chemical solution to the substrate W held by the spin chuck 62 at the processing position, the etching processing on the substrate W proceeds, for example. When the discharge nozzle 65 discharges pure water to the substrate W, pure water rinsing processing on the substrate W proceeds.

A plurality of sensor not shown in the diagrams are provided to the substrate processing apparatus 50. A sensor detecting breakage of the substrate W is provided to each processing unit 52 of the substrate processing apparatus 50, for example. A sensor detecting leakage (liquid leakage) of a processing solution is provided to the substrate processing apparatus 50, for example. Furthermore, a sensor detecting collusion of the main transport robot 57 or the transfer robot 56 is provided to the substrate processing apparatus 50, for example.

A worker performing an operation, for example, on the plurality of substrate processing apparatuses 50 disposed in the clean room 40 wears the smart glass 10. The smart glass 10 is a type of a wearable terminal of a head mount display (HMD) system. The smart glass 10 is also a device for achieving augmented reality (AR) or mixed reality (MR). HoloLens (registered trademark) made by Microsoft Corporation, for example, can be used as the smart glass 10.

FIG. 7 is a perspective view illustrating an appearance of the smart glass 10. The smart glass 10 includes a visor 11 and a headband 12. The worker puts the headband 12 on a head to wear the smart glass 10. The worker can adjust a length of the headband 12 in accordance with a size of his/her head. A power source button, a light button, and a volume button, for example, are provided to the headband 12.

The visor 11 includes various sensors and a display. The display is a see-through holographic lens. That is to say, the display can display a three-dimensional vision on a visual space of the worker by a hologram, and light from an actual object passes through the display in the manner similar to a normal eyeglass lens. Accordingly, the worker wearing the smart glass 10 can also see a displayed three-dimensional vision while visually recognizing an actual object through the display.

Examples of the sensor of the visor 11 include a plurality of visible light cameras mainly taking an image in front of the visor 11, an infrared camera tracking a visual line of the worker, a depth sensor measuring a distance to a target object, and an inertial measurement sensor. The depth sensor measures a distance to a target object by a time of flight (ToF) system, for example. The inertial measurement sensor is made up of an accelerometer, a gyroscope, and a magnetometer, for example.

The smart glass 10 includes a built-in computer including a CPU, a memory, and a storage part, for example. A wireless communication mechanism is also provided to the smart glass 10, and the computer of the smart glass 10 is connected to the information communication network 5 using the wireless communication mechanism. Furthermore, a microphone, a speaker, and a battery, for example, are also provided to the smart glass 10.

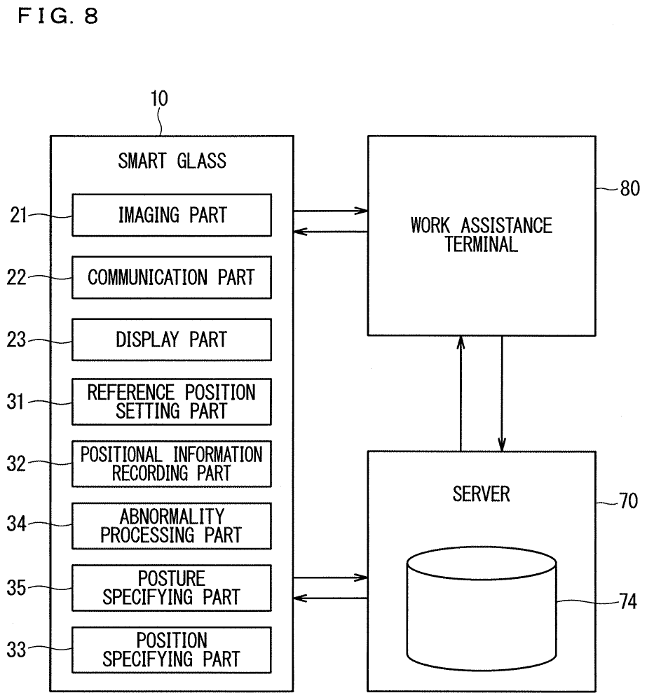

FIG. 8 is a block diagram illustrating a functional configuration of the smart glass 10, the server 70, and the work assistance terminal 80. The smart glass 10 includes an imaging part 21, a communication part 22, and a display part 23. The imaging part 21 includes a visible light camera provided to the visor 11 described above. The imaging part 21 includes four visible light cameras taking images of a front side and an obliquely front side, for example, and can take the image of a visual field range of the worker wearing the smart glass 10.

The communication part 22 includes the wireless communication mechanism of the smart glass 10 described above. The communication part 22 transmits and receives data to and from the work assistance terminal 80 and the server 70 via the information communication network 5. The communication part 22 can also transmit and receive the data to and from the controller 55 of the substrate processing apparatus 50.

The display part 23 includes a display of the visor 11 described above. The display part 23 includes a holographic processing device, and displays a three-dimensional vision in a predetermined spatial position by a hologram technique. The three-dimensional vision displayed by the display part 23 is not limited to video having a three-dimensional shape. A two-dimensional video such as a document is also applicable.

The smart glass 10 includes a reference position setting part 31, a positional information recording part 32, a position specifying part 33, an abnormality processing part 34, and a posture specifying part 35. The reference position setting part 31, the positional information recording part 32, the position specifying part 33, the abnormality processing part 34, and the posture specifying part 35 are function processing parts achieved by a CPU of the smart glass 10 executing a predetermined processing program. Processing contents of the reference position setting part 31, the positional information recording part 32, the position specifying part 33, the abnormality processing part 34, and the posture specifying part 35 will be described in more detail hereinafter.

The work assistance terminal 80 and the server 70 are disposed in a plant of a vendor manufacturing the substrate processing apparatus 50 and undertaking a maintenance check, for example. The work assistance terminal 80 and the server 70 can have communication with the smart glass 10 via the information communication network 5. The work assistance terminal 80 and the server 70 can also have mutual communication with each other via the information communication network 5.

The work assistance terminal 80 and the server 70 are general computer systems. That is to say, the work assistance terminal 80 and the server 70 include a CPU that is a circuit for performing various types of computation processing, a ROM or read-only memory for storing a basic program therein, a RAM or readable/writable memory for storing various types of information therein, a storage part (for example, a magnetic disk or an SSD) for storing control software, data and the like therein, and a communication part having communication with the information communication network 5.

The work assistance terminal 80 is a computer for a work assistant on a vendor side to assist a work of a worker in the clean room 40. The work assistant can transmit various types of information from the work assistance terminal 80 to the smart glass 10 which the worker in the clean room 40 wears.

The server 70 is a computer executing predetermined processing in accordance with request from the smart glass 10 and the work assistance terminal 80 in the work assistance system according to the present invention. Ther server 70 includes a storage part 74 having relatively large capacity. Large size data created by the smart glass 10 and the work assistance terminal 80 may be stored in the storage part 74. The server 70 is not a necessary element.

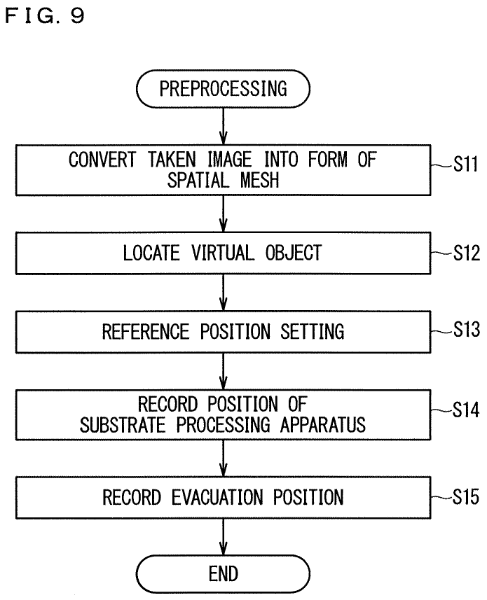

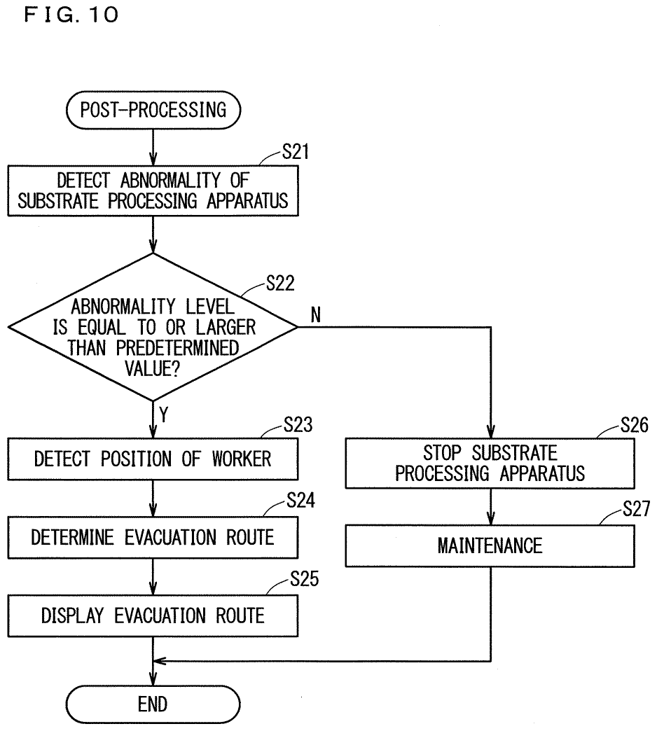

A work assistance method using the work assistance system having the above configuration is described next. FIG. 9 and FIG. 10 are flow charts each illustrating a procedure of the work assistance method according to the present invention. The work assistance method according to the present invention is divided into previous preparation processing and post-processing at a time of actually working. FIG. 9 illustrates a procedure of the preprocessing, and FIG. 10 illustrates a procedure of the post-processing.

There is a description hereinafter that the worker performs an operation of selection or input, for example, using the three-dimensional vision displayed by the display part 23 of the smart glass 10 in some cases. This means that when the worker performs the operation of selection or input, for example, by a hand gesture on the three-dimensional vision displayed by the display part 23, the imaging part 21 takes an image of the hand gesture and detects the hand gesture, and the computer of the smart glass 10 recognizes that a predetermined operation is performed from a detection result thereof.

In the previous preparation process, an image of part of an inner side of the clean room 40 is taken by the smart glass 10, and the taken image is converted into a form of a spatial mesh (Step S11). This processing is performed by the worker wearing the smart glass 10 in the clean room 40 using the smart glass 10, for example.

The worker switches on a scan mode preset in the smart glass 10. The worker can select the scan mode from a menu screen displayed as a three-dimensional vision by the display part 23 by a hand gesture and switch on the scan mode, for example. The imaging part 21 takes the image of the hand gesture and detects the hand gesture, and the computer of the smart glass 10 recognizes that the scan mode is selected from a detection result thereof. Alternatively, the worker may press a predetermined button provided to the smart glass 10, thereby switching on the scan mode.

The worker takes an image of one or some of the plurality of substrate processing apparatuses 50 disposed in the clean room 40 by the imaging part 21 while the scan mode is in an on state. The image taken in the on state of the scan mode is scanned by the smart glass 10 and converted into the form of the spatial mesh, and the display part 23 displays the taken image overlapped with a mesh graphic.

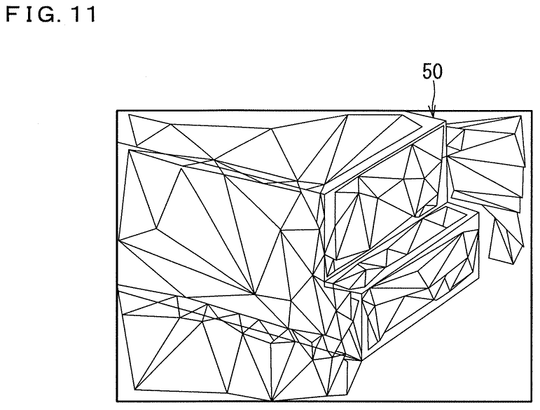

FIG. 11 is a diagram illustrating an example of the taken image converted into the form of the spatial mesh. The imaging part 21 takes the image of the substrate processing apparatus 50, and the taken image is scanned and converted into the form of the spatial mesh. Thus, the mesh graphic expressed by a large number of triangle meshes is overlapped with the image of the substrate processing apparatus 50 and displayed. Even in a case where the same type and same form (that is to say, the same appearance) of plurality of substrate processing apparatuses 50 are disposed in the clean room 40, when the image of the plurality of substrate processing apparatuses 50 are taken and converted into the form of the spatial mesh, the mesh graphic is created in a different form because of a minute difference (for example, difference of a situation of a path) around each substrate processing apparatus 50. Accordingly, the taken image of the plurality of substrate processing apparatuses 50 in the clean room 40 can be identified by the difference of the mesh graphic.

After the taken image of the substrate processing apparatus 50 is converted into the form of the spatial mesh, the worker locates a virtual object on the spatial mesh in the image (Step S12). The virtual object is a virtual marker displayed by a three-dimensional vision by the display part 23. The worker locates the virtual object in an optional position around the substrate processing apparatus 50 by a hand gesture in the meshed image illustrated in FIG. 11, for example. Subsequently, the worker may fine-adjust the position of the virtual object using a remote controller screen displayed as a three-dimensional vision by the display part 23. The position where the virtual object is disposed may be overlapped with the substrate processing apparatus 50.

When the virtual object is disposed in the taken image of the substrate processing apparatus 50, the reference position setting part 31 of the smart glass 10 sets the position of the virtual object as a reference position with respect to the substrate processing apparatus 50 (Step S13). When the virtual object is disposed on the spatial mesh in the taken image, the reference position setting part 31 recognizes a position of the virtual object itself using a characteristic part of the spatial mesh. The characteristic part of the spatial mesh is a part having a characteristic mesh form such as a corner part of the substrate processing apparatus 50 in scanning, for example.

Next, the position of the substrate processing apparatus 50 is calculated and recorded based on the reference position set by locating the virtual object (Step S14). The worker overlaps a CAD diagram of the substrate processing apparatus 50 with a region of the substrate processing apparatus 50 in the taken image, for example. At this time, a 3D-CAD diagram is preferably overlapped with the substrate processing apparatus 50. The CAD diagram of the substrate processing apparatus 50 is previously created in designing the apparatus, and data thereof is stored in the storage part 74 of the server 70, for example. The smart glass 10 reads out the data of the CAD diagram of the substrate processing apparatus 50 from the server 70, and the display part 23 displays the CAD diagram in the taken image. The worker moves the displayed CAD diagram by a hand gesture to overlap the CAD diagram with the region of the substrate processing apparatus 50. Also at this time, the worker may fine-adjust the position of the CAD diagram using a remote controller screen displayed as a three-dimensional vision by the display part 23.

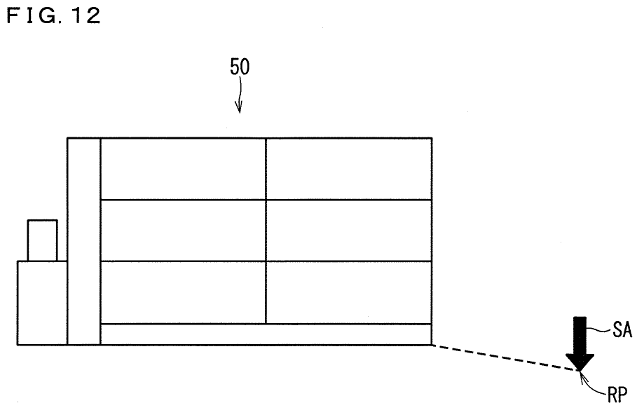

When the CAD diagram of the substrate processing apparatus 50 is accurately overlapped with the region of the substrate processing apparatus 50 in the taken image, the positional information recording part 32 of the smart glass 10 calculates a relative positional relationship between the reference position described above (the position of the virtual object) and any portion of the substrate processing apparatus 50 and records the relative positional relationship. FIG. 12 is a diagram schematically illustrating the relative positional relationship between the reference position and the substrate processing apparatus 50. When a virtual object SA is disposed, a position thereof is recorded as a reference position RP. A position of the portion included in the substrate processing apparatus 50 can be obtained by coordinate information included in the CAD data. The positional information recording part 32 calculates the relative positional relationship between the reference position RP and any portion of the substrate processing apparatus 50 (for example, a corner of the substrate processing apparatus 50) based on information of the reference position RP set in Step S13 and the coordinate information of the data of the CAD diagram overlapped with the substrate processing apparatus 50, and records the relative positional relationship.

The data of the CAD diagram also includes coordinate information of the processing unit 52 included in the substrate processing apparatus 50 and the portion (for example, the spin chuck 62 and the discharge nozzle 65) provided to the processing unit 52. Accordingly, the positional information recording part 32 may calculate the relative positional relationship between each of the plurality of processing units 52 mounted to the substrate processing apparatus 50 and the reference position RP, and record the relative positional relationship. The positional information recording part 32 may further calculate a relative positional relationship between a portion provided to each processing unit 52 and the reference position RP, and record the relative positional relationship. As for a driving portion such as the discharge nozzle 65, the coordinate information included in the data of the CAD diagram is based on a home position. Thus, calculated is the relative positional relationship between the driving portion located in the home position (a standby position described above in a case of the discharge nozzle 65) and the reference position RP.

It is sufficient that the positional information recording part 32 writes the calculated relative positional relationship between the reference position RP and the substrate processing apparatus 50 in a database, for example, and records the relative positional relationship. Specifically, the positional information recording part 32 mutually associates an object name of a virtual object, a device number of the substrate processing apparatus 50 associated with the object name, and relative positional information of the substrate processing apparatus 50, for example, with each other, and records data thereof in the database.

In the first embodiment, the processing of Step S11 to Step S14 is repetitively performed on all of the plurality of substrate processing apparatuses 50 disposed in the clean room 40 as the previous preparation processing. That is to say, the virtual object is disposed for all of the plurality of substrate processing apparatuses 50 disposed in the clean room 40, and the relative positional relationship between the reference position and the substrate processing apparatus 50 is calculated and recorded. The relative positional information of each of the plurality of substrate processing apparatuses 50 are sequentially recorded in the database to constitute the database. Such a database is stored in the storage part 74 of the server 70, for example.

When the processing of conversion into the form of the spatial mesh in Step S11 is repetitively performed, conversion into the form of the spatial mesh is performed over a large range in the clean room 40. Accordingly, the smart glass 10 can recognize the position of the virtual object over a large range in the clean room 40. That is to say, the smart glass 10 can recognize in which position each of the plurality of disposed virtual objects is disposed in the clean room 40.

The smart glass 10 recognizes the position of each of the plurality of virtual objects in the clean room 40, and the relative positional information of each of the plurality of substrate processing apparatuses 50 with respect to the reference position RP as the position where the virtual object is disposed is sequentially recorded in the database. Accordingly, the position of each of the plurality of substrate processing apparatuses 50 in the clean room 40 is specified and recorded.

After the position of the substrate processing apparatus 50 is recorded, an evacuation position is recorded (Step S15). An evacuation port 44 is provided to the clean room 40 for emergency evacuation as illustrated in FIG. 2. In the first embodiment, a position of the evacuation port 44 is the evacuation position. The position of the evacuation port 44 is a fixed position. The worker also records the position of the evacuation port 44 in the clean room 40 using the smart glass 10. Specifically, an image of the evacuation port 44 which the worker sees through the smart glass 10 is scanned and converted into the form of the spatial mesh to record the position of the evacuation port 44 in the clean room 40.

The operation assistant may record additional information regarding the substrate processing apparatus 50 from the operation assistance terminal 80 together with the positional information of each of the plurality of substrate processing apparatuses 50. Examples of the additional information include alarm information, a work history, diagram information, and a work procedure document. It is sufficient that the previous preparation processing in Step S11 to Step S15 is performed once when the plurality of substrate processing apparatuses 50 are disposed in the clean room 40, for example.

Described next with reference to FIG. 10 is post-processing at a time of occurrence of abnormality in any of the plurality of substrate processing apparatuses 50 when the worker works in the clean room 40. The worker wearing the smart glass 10 works in the clean room 40. At least some of the plurality of substrate processing apparatuses 50 disposed in the clean room 40 are activated and perform substrate processing.

Firstly, abnormality occurs in any of the plurality of substrate processing apparatuses 50 disposed in the clean room 40, and is detected (Step S21). Various sensors for detecting abnormality are provided to the substrate processing apparatus 50. When the sensor detects some kind of abnormality, the controller 55 of the substrate processing apparatus 50 emits alarm information. For example, when the sensor detects leakage of a processing solution, the controller 55 of the substrate processing apparatus 50 emits alarm information indicating occurrence of liquid leakage. When the sensor detects a crack of the substrate W during processing in the processing unit 52, the controller 55 emits alarm information indicating occurrence of wafer crack.

The alarm information emitted from the controller 55 of the substrate processing apparatus 50 is also transmitted to the smart glass 10 which the worker wears via the information communication network 5. At this time, an abnormality level thereof is also transmitted from the controller 55 to the smart glass 10 together with the alarm information. Specifically, it is sufficient that a table associating contents of abnormality with an abnormality level is previously prepared, and when the sensor detects some kind of abnormality, the controller 55 emits the abnormality level based on the table, for example. For example, when the sensor detects leakage of a risky processing solution such as hydrofluoric acid or processing gas, an abnormality level having a high value is transmitted. When the substrate W is merely cracked, an abnormality level having a relatively low value is transmitted, for example.

Upon receiving the alarm information of occurrence of abnormality, the abnormality processing part 34 of the smart glass 10 determines whether or not a value of an abnormality level of the alarm information is equal to or larger than a predetermined threshold value (Step S22). The value of the abnormality level smaller than the predetermined threshold value indicates that a relatively small degree of abnormality occurs. In this case, the process proceeds to Step S26 from Step S22, and the substrate processing apparatus 50 in which the abnormality occurs is temporarily stopped. Then, the worker performs maintenance on the substrate processing apparatus 50 (Step S27). For example, when the crack of the substrate W occurs in the processing unit 52, the worker performs cleaning work of removing a broken piece of the substrate W from the processing unit 52.

Before the maintenance, the smart glass 10 may display positional information of the substrate processing apparatus 50 (the substrate processing apparatus 50 on which the maintenance is to be performed) in which the abnormality occurs. Specifically, the position specifying part 33 of the smart glass 10 extracts the virtual object and the relative position information associated with the substrate processing apparatus 50 in which the abnormality occurs, for example, from the database. The smart glass 10 recognizes where the virtual object is disposed in the clean room 40 using the spatial mesh. The relative positional information extracted from the database is a relative coordinate of the substrate processing apparatus 50 with respect to the reference position RP as the position where the virtual object is disposed. Accordingly, the position specifying part 33 of the smart glass 10 can specify the position of the substrate processing apparatus 50 in which the abnormality occurs in the clean room 40 based on the reference position RP as the position where the virtual object is disposed associated with the substrate processing apparatus 50 to be worked on and the relative positional information as the relative coordinate with respect to the reference position RP.

After the position of the substrate processing apparatus 50 in which the abnormality occurs is specified, the position specifying part 33 makes the display part 23 display the positional information of the specified substrate processing apparatus 50. For example, it is sufficient that the display part 23 emphatically displays the substrate processing apparatus 50 in which the abnormality occurs in the image which the worker sees through the smart glass 10. The display part 23 may display a guide route from a current position of the worker to the substrate processing apparatus 50 in which the abnormality occurs. An arrow for guidance may be displayed on a path in the clean room 40 which the worker sees through the smart glass 10.

In the meanwhile, the value of the abnormality level equal to or larger than the predetermined threshold value indicates that a relatively risky abnormality occurs. In this case, evacuation for ensuring safety of the worker takes priority over the maintenance. When the value of the abnormality level is equal to or larger than the predetermined threshold value, the process proceeds from Step S22 to Step S23, and the position specifying part 33 of the smart glass 10 detects the current position (position at a time of alarm emission) of the worker. The position of the worker wearing the smart glass 10 can be specified when an image of a visual field which the worker sees through the smart glass 10 is converted into the form of spatial mesh. The worker switches on the scan mode while seeing an appropriate region in the clean room 40 through the smart glass 10. Alternatively, the abnormality processing part 34 of the smart glass 10 may automatically switch on the scan mode when the alarm information of occurrence of abnormality is received. Accordingly, the image of the visual field which the worker sees through the smart glass 10 is scanned and converted into the form of the spatial mesh. The smart glass 10 performs pattern matching of the image converted into the form of the spatial mesh and the image converted into the form of the spatial mesh over the large range in the clean room 40 in the previous preparation processing, thereby specifying the current position of the worker in the clean room 40.

Subsequently, the abnormality processing part 34 of the smart glass 10 determines an evacuation route connecting the current position of the worker and the evacuation position (the position of the evacuation port 44) in the clean room 40 (Step S24). At this time, a shortest route from the current position of the worker to the evacuation position is preferably determined as the evacuation route. However, the abnormality processing part 34 gives priority to determine a route away from the substrate processing apparatus 50 in which the abnormality occurs as the evacuation route over the distance.

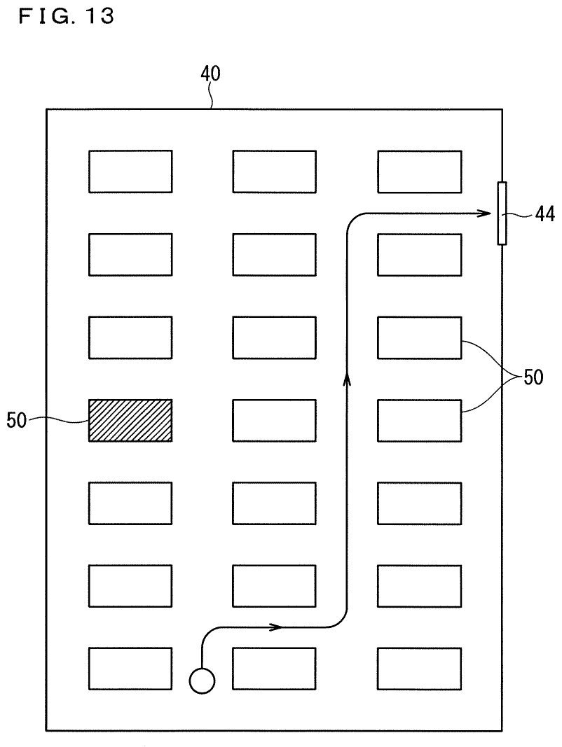

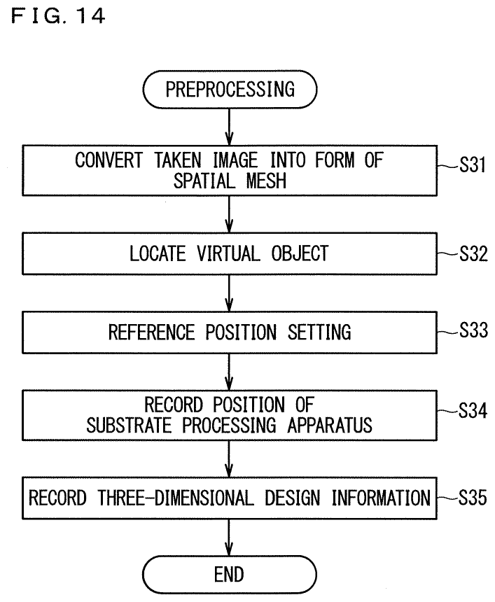

After the evacuation route is determined, the abnormality processing part 34 of the smart glass 10 makes the display part 23 display the evacuation route from the current position of the worker to the evacuation port 44 on the display part 23 as illustrated in FIG. 13 (Step S25). In FIG. 13, a hatching is assigned to the substrate processing apparatus 50 in which the abnormality occurs. As illustrated in FIG. 13, determined is the evacuation route away from the substrate processing apparatus 50 in which the abnormality occurs from the current position of the worker to the evacuation port 44. Although displayed in FIG. 13 is the evacuation route in an image of seeing the inner side of the clean room 40 from an upper side in a plan view, the display is not limited thereto. For example, an arrow for guidance may be displayed on a path in the actual clean room 40 which the worker sees through the smart glass 10.

The worker proceeds along the evacuation route displayed by the smart glass 10, thereby being able to safely reach the evacuation port 44 to get out of the clean room 40.

In the first embodiment, the position where the virtual object is disposed is set as the reference position RP, and the relative positional relationship of the substrate processing apparatus 50 with respect to the reference position RP is calculated and recorded to recognize the position of the substrate processing apparatus 50 in the clean room 40. When the abnormality occurs in the substrate processing apparatus 50 and is detected, and the value of the abnormality level is equal to or larger than the predetermined threshold value, the smart glass 10 determines and displays the evacuation route for evacuation of the worker. Accordingly, when the abnormality occurs in the substrate processing apparatus 50, the worker working in the clean room 40 can easily recognize the evacuation route and safely get out.

In the example described above, the evacuation position is the position of the evacuation port 44, but is not limited thereto. A safe area preset in the clean room 40 may be the evacuation position, for example.

### Second Embodiment

Next, a second embodiment of the present invention will be described. A whole configuration of a work assistance system, arrangement of the plurality of substrate processing apparatuses 50 in the clean room 40, and a configuration of each substrate processing apparatus 50 in the second embodiment are the same as those in the first embodiment. Although the abnormality occurs during the work of the worker outside the substrate processing apparatus 50 in the first embodiment, the second embodiment is directed to a coping method in a case where the abnormality occurs when the worker enters inside the substrate processing apparatus 50 and works therein.

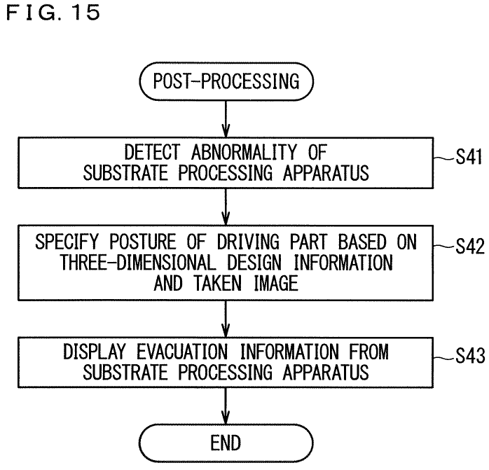

FIG. 14 and FIG. 15 are flow charts illustrating a procedure of a work assistance method according to the second embodiment. The work assistance method is divided into previous preparation processing and post-processing at a time of actually working in the manner similar to the first embodiment. FIG. 14 illustrates a procedure of the preprocessing, and FIG. 15 illustrates a procedure of the post-processing.

Steps S31 to S34 in FIG. 14 are the same as Steps S11 to S14 in FIG. 9. That is to say, the image of part of the inner side of the clean room 40 including the substrate processing apparatus 50 is firstly taken by the smart glass 10, and the taken image is converted into the form of the spatial mesh (Step S31). Next, the virtual object is disposed on the spatial mesh in the taken image including the substrate processing apparatus 50 (Step S32). When the virtual object is disposed in the taken image of the substrate processing apparatus 50, the position of the virtual object is set as the reference position with respect to the substrate processing apparatus 50 (Step S33). Then, the position of the substrate processing apparatus 50 is calculated and recorded based on the reference position set by locating the virtual object (Step S34).

Also in the second embodiment, the processing of Step S31 to Step S34 is repetitively performed on all of the plurality of substrate processing apparatuses 50 disposed in the clean room 40 as the previous preparation processing. That is to say, the virtual object is disposed for all of the plurality of substrate processing apparatuses 50 disposed in the clean room 40, and the relative positional relationship between the reference position and the substrate processing apparatus 50 is calculated and recorded. The relative positional information of each of the plurality of substrate processing apparatuses 50 are sequentially recorded in the database to constitute the database.

When the processing of conversion into the form of the spatial mesh in Step S31 is repetitively performed, conversion into the form of the spatial mesh is performed over a large range in the clean room 40. Accordingly, the smart glass 10 can recognize the position of the virtual object over a large range in the clean room 40. That is to say, the smart glass 10 can recognize in which position each of the plurality of disposed virtual objects is disposed in the clean room 40.

The smart glass 10 recognizes the position of each of the plurality of virtual objects in the clean room 40, and the relative positional information of each of the plurality of substrate processing apparatuses 50 with respect to the reference position RP as the position where the virtual object is disposed is sequentially recorded in the database. Accordingly, the position of each of the plurality of substrate processing apparatuses 50 in the clean room 40 is specified and recorded.

In the second embodiment, three-dimensional design information of the processing part included in the substrate processing apparatus 50 is further obtained and recorded (Step S35). The three-dimensional design information is 3D-CAD data, for example, and is stored in the storage part 74 of the server 70. Herein, “the processing part” is an element performing an action on the substrate W, and includes the transfer robot 56 and the main transport robot 57 in addition to the spin chuck 62 and the discharge nozzle 65 provided to the processing unit 52.

The three-dimensional design information may recorded by a work assistant using the work assistance terminal 80, for example. Specifically, it is sufficient that the operation assistance terminal 80 records a file name of the three-dimensional design information of the processing part included in the substrate processing apparatus 50 in association with the substrate processing apparatus 50 in the database described above in response to the input operation on the operation assistance terminal 80 by the operation assistant, for example.

In Step S35, it is sufficient that the three-dimensional design information of at least the driving part in the processing parts included in the substrate processing apparatus 50 is recorded. “The driving part” is an element performing some action in the processing part, and includes the discharge nozzle 65 performing a pivot operation, the transfer robot 56, and the main transport robot 57, for example.

The post-processing in the second embodiment is based on a premise that the worker enters inside any of the plurality of substrate processing apparatuses 50 disposed in the clean room 40 and works therein. The worker wears the smart glass 10, and moves inside the clean room 40 while the scan mode is in the on state to reach the substrate processing apparatus 50 to be worked on. When the worker reaches the substrate processing apparatus 50 to be worked on while scanning the image of the visual field which the worker sees through the smart glass 10, the smart glass 10 performs pattern matching between the image converted into the form of the spatial mesh and the image converted into the form of the spatial mesh in the previous preparation processing and specifies the position in the clean room 40 of the substrate processing apparatus 50 to be worked on. That is to say, even when the worker works inside the substrate processing apparatus 50, the smart glass 10 recognizes an identification number and the position of the substrate processing apparatus 50.

When the worker works inside the substrate processing apparatus 50 to be worked on, abnormality occurs in the substrate processing apparatus 50 and is detected (Step S41). In the manner similar to the first embodiment, when the sensor provided to the substrate processing apparatus 50 detects abnormality, the controller 55 of the substrate processing apparatus 50 emits alarm information.

The alarm information emitted from the controller 55 is transmitted to the smart glass 10 which the worker wears via the information communication network 5. The smart glass 10 may directly provide and receive information to and from the controller 55 of the substrate processing apparatus 50 in which the worker is working by near field communication such as Bluetooth (registered trademark), for example.

Upon receiving the alarm information of occurrence of abnormality, the abnormality processing part 34 of the smart glass 10 takes an image of a visual field range of the smart glass 10 at the time of receiving the alarm information and converts the image info the form of the spatial mesh. Accordingly, the smart glass 10 can identify the processing part in the substrate processing apparatus 50 included in the visual field range. Then, the posture specifying part 35 of the smart glass 10 reads out the three-dimensional design information of the driving part in the processing part included in the visual field range, and specifies a posture of the driving part based on the three-dimensional design information and the taken image of the driving part (Step S42).

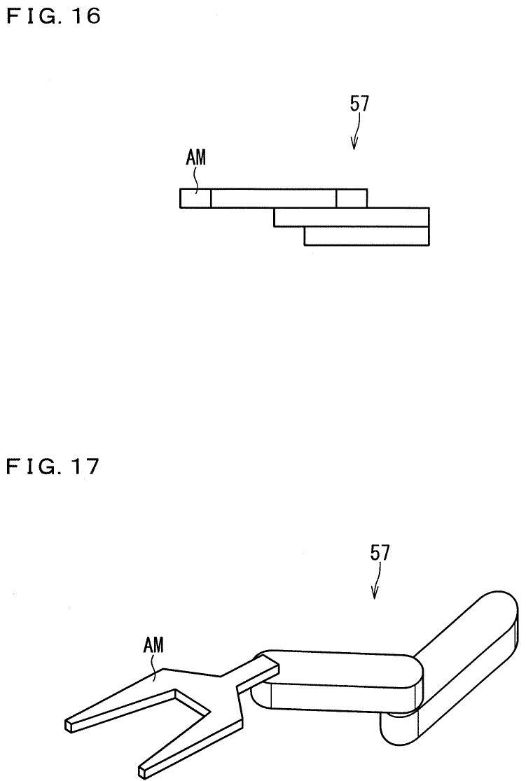

FIG. 16 is a diagram illustrating an image of the driving part taken by the smart glass 10 at the time of receiving the alarm information. In the example in FIG. 16, the smart glass 10 takes the image of the main transport robot 57. Immediately before receiving the alarm information, the worker worked in front of the main transport robot 57 inside the substrate processing apparatus 50. Thus, the visual field range of the smart glass 10 includes the main transport robot 57 at the time of receiving the alarm information, and the smart glass 10 takes the image of the main transport robot 57. However, the image taken by the smart glass 10 is a two-dimensional image. Thus, as illustrated in FIG. 16, the image of the main transport robot 57 taken by the smart glass 10 at the time of receiving the alarm information is the two-dimensional image of the transport arm AM seen from a front side. A posture of the main transport robot 57 cannot be determined from the two-dimensional image of the main transport robot 57 as illustrated in FIG. 16 taken by the smart glass 10.

Thus, the posture specifying part 35 of the smart glass 10 specifies the posture of the main transport robot 57 at a point of time when the alarm information is received based on the three-dimensional design information and the taken image of the main transport robot 57. FIG. 17 is a diagram illustrating a posture of a driving part (the main transport robot 57 herein) specified by the posture specifying part 35 of the smart glass 10. The posture specifying part 35 specifies a three-dimensional posture of the main transport robot 57 based on the three-dimensional design information and the taken image. Accordingly, the smart glass 10 can recognize even the posture of the main transport robot 57 such as a position and a direction of the transport arm AM which cannot be determined by only the taken image, for example.

Next, the abnormality processing part 34 of the smart glass 10 makes the display part 23 display information for evacuating from the substrate processing apparatus 50 (Step S43). The smart glass 10 displays the information for evacuating from the substrate processing apparatus 50 based on the posture of the driving part specified in Step S42. For example, in the above example, the posture of the main transport robot 57 at a point of time when the alarm information is received is specified in Step S42. Accordingly, the smart glass 10 recognizes the posture of the main transport robot 57, and displays the information for evacuating from the substrate processing apparatus 50 corresponding to the posture thereof. For example, when the transport arm AM is located above the transport area as the posture of the main transport robot 57 recognized by the smart glass 10, the smart glass 10 displays information such as “attention to transport arm above”.

The worker considers the evacuation information displayed by the smart glass 10, thereby being able to safely evacuate from the substrate processing apparatus 50 in which the abnormality occurs while avoiding collision with the main transport robot 57, for example.

In the second embodiment, when abnormality of the substrate processing apparatus 50 is detected during a work of the worker in that substrate processing apparatus 50, the posture specifying part 35 of the smart glass 10 specifies the posture of the driving part based on the image of the driving part taken by the smart glass 10 and the three-dimensional design information of the driving part. Then, the smart glass 10 displays the information for the worker to evacuate from the substrate processing apparatus 50 based on the posture of the specified driving part. Accordingly, when the abnormality occurs in the substrate processing apparatus 50, the worker working in the substrate processing apparatus 50 can safely get out of the apparatus.

In the above example, the information for evacuation is displayed based on the posture of the main transport robot 57. However, it is also applicable that the other element as the driving part such as the posture of the discharge nozzle 65 is specified and the information for evacuating from the substrate processing apparatus 50 may be displayed based on the posture, for example. Alternatively, it is also applicable that a state of discharging a processing solution is specified from a state of the processing part other than the driving part at the time of detecting the abnormality of the substrate processing apparatus 50 such as an edge rinse nozzle which is fixedly disposed, and the information for evacuating from the substrate processing apparatus 50 such as “attention to rinse solution” is displayed based on the state thereof. For example, the discharge state of the processing solution from the edge rinse nozzle can be specified when the smart glass 10 obtains sensor data from the substrate processing apparatus 50.

### Third Embodiment

Next, a third embodiment of the present invention will be described. A whole configuration of a work assistance system, arrangement of the plurality of substrate processing apparatuses 50 in the clean room 40, and a configuration of each substrate processing apparatus 50 in the third embodiment are the same as those in the first embodiment. In the third embodiment, when abnormality is detected in any of the plurality of substrate processing apparatuses 50 disposed in the clean room 40, the smart glass 10 displays coping information for coping with the abnormality.

As illustrated in FIG. 3, the accessory unit 48 is provided to each of the plurality of substrate processing apparatuses 50 separately from a body. The substrate processing apparatus 50 is disposed on the floor 45 of the clean room 40, and the accessory unit 48 is provided below the floor 45. The plurality of substrate processing apparatuses 50 and the plurality of accessory units 48 are provided to correspond to each other on a one-to-one basis. Since the accessory unit 48 is provided to the floor different from the substrate processing apparatus 50 as the body, it is difficult to recognize which is a unit corresponding to the substrate processing apparatus 50 in the plurality of accessory units 48 disposed in the different floor.

In the third embodiment, the worker wearing the smart glass 10 also locates the virtual object around the accessory unit 48 in addition to locating the virtual object around the substrate processing apparatus 50. In the manner similar to the first embodiment, the worker converts a taken image including the accessory unit 48 taken by the smart glass 10 into a form of a spatial mesh. Then, the worker locates the virtual object on the spatial mesh. The virtual object may be disposed in an optional position around the accessory unit 48.

Since the virtual object is disposed in the taken image of the accessory unit 48, the reference position setting part 31 of the smart glass 10 sets the position of the virtual object as an accessory reference position with respect to the accessory unit 48. Then, the positional information recording part 32 of the smart glass 10 calculates the relative positional relationship between the accessory reference position and the accessory unit 48, and records the relative positional relationship. It is sufficient that the relative positional relationship is calculated by overlapping a 3D-CAD diagram of the accessory unit 48 with the accessory unit 48, for example, in the manner similar to the first embodiment. The calculated relative positional relationship between the accessory reference position and the accessory unit 48 is read in the database as the positional information.

The reference position RP of the substrate processing apparatus 50 and the accessory reference position of the accessory unit 48 of the substrate processing apparatus 50 are associated with each other in recording the database. Specifically, an object name of the virtual object disposed with respect to the substrate processing apparatus 50 and an object name of the virtual object disposed with respect to the accessory unit 48 of the substrate processing apparatus 50 have a common part, for example. Accordingly, both virtual objects are linked to each other, and the reference position RP of the substrate processing apparatus 50 and the accessory reference position of the accessory unit 48 of the substrate processing apparatus 50 are associated with each other.

The post-processing in the third embodiment is based on a premise that leakage of a processing solution occurs as abnormality in any of the plurality of substrate processing apparatuses 50 disposed in the clean room 40. The liquid leakage is detected by the sensor of the substrate processing apparatus 50, and the controller 55 emits alarm information indicating that the liquid leakage occurs.

The alarm information emitted from the controller 55 of the substrate processing apparatus 50 is also transmitted to the smart glass 10 which the worker wears via the information communication network 5. In the manner similar to the first embodiment, an abnormality level is also transmitted from the controller 55 to the smart glass 10 together with the alarm information.

In the third embodiment, when a value of the abnormality level is smaller than a predetermined threshold value and contents of the alarm information indicates the liquid leakage, the smart glass 10 displays coping information for canceling the alarm. Specifically, the smart glass 10 displays positional information of the accessory unit 48 as a chemical solution cabinet supplying a processing solution to the substrate processing apparatus 50 in which the liquid leakage occurs, and displays advice for operating the accessory unit 48 to stop supplying the processing solution to the substrate processing apparatus 50.

It is sufficient that the positional information of the accessory unit 48 corresponding to the substrate processing apparatus 50 in which the liquid leakage occurs is displayed as follows. The position specifying part 33 of the smart glass 10 specifies the position of the accessory unit 48 of the substrate processing apparatus 50 in which the liquid leakage occurs. Specifically, the position specifying part 33 specifies the accessory unit 48 corresponding to the object name linked to the object name corresponding to the substrate processing apparatus 50 in which the liquid leakage occurs from the database. Then, the position specifying part 33 extracts the positional information associated with the specified accessory unit 48, and specifies the position of the accessory unit 48 to be worked on based on the accessory reference position and the positional information as the relative coordinate with respect to the accessory reference position.

After the position of the accessory unit 48 to be worked on is specified, the position specifying part 33 makes the display part 23 display the positional information of the specified accessory unit 48. As the display of the positional information, it is sufficient to specify the current position of the worker based on the image taken by the smart glass 10 and display the guide route from the current position to the accessory unit 48 to be worked on in the manner similar to the first embodiment, for example.

The worker reaches the accessory unit 48 corresponding to the substrate processing apparatus 50 in which the liquid leakage occurs in accordance with the coping information displayed by the smart glass 10, and performs an operation of stopping supplying the processing solution to the substrate processing apparatus 50 on the accessory unit 48. Accordingly, the alarm is canceled.

In the third embodiment, when the abnormality is detected in any of the plurality of substrate processing apparatuses 50, the smart glass 10 displays the coping information for coping with the abnormality. Accordingly, when the abnormality occurs in the substrate processing apparatus 50, the worker can perform an appropriate coping along the displayed coping information and cancel the abnormality.

Although the worker performs the necessary operation on the accessory unit 48 to cope with the abnormality in the above example, the worker may operate the other element (for example, a processing solution valve) to cope with the abnormality. In this case, for example, it is sufficient that the smart glass 10 emphatically displays the processing solution valve of the processing unit 52 in which the liquid leakage occurs and displays advice to close the processing solution valve to stop supplying the processing solution. In short, it is sufficient that the smart glass 10 displays the positional information of the element relating to the abnormality occurring in the substrate processing apparatus 50 and displays the information regarding the necessary operation on the element to cancel the abnormality.

### Modification Example

While the embodiments according to the present invention have been described hereinabove, various modifications of the present invention are possible in addition to those described above without departing from the scope and spirit of the present invention. For example, in the first embodiment, when the abnormality occurs in the substrate processing apparatus 50, the coping is determined in accordance with the value of the abnormality level of the alarm information. However, the configuration is not limited thereto. The coping may be determined based on the image taken by the smart glass 10. In this case, an image of each processing part in a normal state included in the substrate processing apparatus 50 is taken by the smart glass 10 and stored as the previous preparation processing. Alternatively, the three-dimensional design information of each processing part included in the substrate processing apparatus 50 may be obtained and recorded in the manner similar to the second embodiment.

When the abnormality occurs in the substrate processing apparatus 50 and is detected, the worker takes the image of the processing part of the substrate processing apparatus 50 using the smart glass 10. The smart glass 10 compares the image of the processing part taken at the time of occurrence of abnormality with the image of the processing part in the normal state which has been taken as preprocessing to perform matching. As a result, when a matching score is larger than a first threshold value, that is to say, when a degree of coincidence between the taken image and the image in the normal state is high, the smart glass 10 determines that the processing part is normal and displays that the processing part is safe. When the matching score is between the first threshold value and a second threshold value (wherein, the second threshold value is smaller than the first threshold value), that is to say, when a degree of coincidence between the taken image and the image in the normal state is a medium degree, the smart glass 10 transmits the alarm information and displays the coping information as with the third embodiment. In the meanwhile, when the matching score is smaller than the second threshold value, that is to say, when a degree of coincidence between the taken image and the image in the normal state is low, the smart glass 10 determines that the processing part is risky and displays the evacuation route to the evacuation position as with the first embodiment.

In the first embodiment, the image is taken by the smart glass 10 over the large range in the clean room 40 and is converted into the form of the spatial mesh. However, huge amounts of data are necessary for the conversion into the form of the spatial mesh. Thus, an image of a part of an area in the clean room 40 may be taken to be converted into the form of the spatial mesh.

In each embodiment described above, the virtual object is disposed on the spatial mesh to position a virtual space and an actual space based on the taken image and the scanned spatial information. Although this method is one of visual positioning service/system (VPS) techniques of positioning the virtual space and the actual space, a method of positioning the virtual space and the actual space is not limited thereto described above.

In each embodiment described above, the worker uses the smart glass 10. However, the configuration is not limited thereto, but the worker may use a tablet terminal or a mobile terminal such as a smartphone in place of the smart glass 10. That is to say, it is sufficient to use a mobile terminal including an imaging part and a communication part. When a tablet terminal, for example, is used, the hand of the worker is filled with the tablet terminal; thus, it is preferable to use a wearable terminal such as the smart glass 10.

The substrate processing apparatus 50 is not limited to a substrate cleaning apparatus. Any semiconductor manufacturing apparatus is applicable as long as it performs predetermined processing on a substrate such as a thermal processing apparatus, an exposure apparatus, a coating-developing apparatus, a measuring apparatus, or an inspection apparatus. When the substrate processing apparatus 50 is the substrate cleaning apparatus, a single wafer type cleaning apparatus cleaning a substrate one by one or a batch-type cleaning apparatus collectively cleaning a plurality of substrates is applicable.

### EXPLANATION OF REFERENCE SIGNS

5 information communication network
40
10 smart glass
21 imaging part
22 communication part
23 display part
31 reference position setting part
32 positional information recording part
33 position specifying part
34 abnormality processing part
35 posture specifying part
40 clean room
48 accessory unit
50 substrate processing apparatus
52 processing unit
56 transfer robot
57 main transport robot
70 server
80 work assistance terminal
60 processing chamber
61 rotation holding part
62 spin chuck
65 discharge nozzle
RP reference position
W substrate

1. A work assistance method in occurrence of abnormality in a substrate processing apparatus performing predetermined processing on a substrate, comprising:
(a) taking an image of a plurality of substrate processing apparatuses disposed in a clean room by a mobile terminal including an imaging part and a communication part;
(b) recording positions of the plurality of substrate processing apparatuses in the clean room base on an taken image obtained in (a); and
(c) displaying coping information for coping with abnormality on the mobile terminal when the abnormality is detected in any of the plurality of substrate processing apparatuses.

2. The work assistance method according to claim 1, further comprising:
(d) recording an evacuation position in the clean room; and
(e) detecting a position of the mobile terminal based on an image taken by the mobile terminal when the abnormality is detected, wherein
in (c), an evacuation route from the position of the mobile terminal detected in (e) to the evacuation position is specified and is displayed.

3. The work assistance method according to claim 2, wherein
in (a) and (e), the image taken by the mobile terminal is scanned and converted into a form of a spatial mesh.

4. The work assistance method according claim 1, wherein
the mobile terminal is a smart glass.

5. A work assistance method in occurrence of abnormality in a substrate processing apparatus performing predetermined processing on a substrate, comprising:
(a) specifying a state of a processing part included in a substrate processing apparatus when abnormality of the substrate processing apparatus is detected during a work in the substrate processing apparatus; and
(b) displaying information for evacuating from the substrate processing apparatus on a mobile terminal including an imaging part and a communication part based on the state of the processing part specified in (a).

6. The work assistance method according to claim 5, further comprising
(c) obtaining and recording three-dimensional design information regarding at least a driving part in a processing part included in the substrate processing apparatus, wherein
in (a), a posture of the driving part is specified based on the three-dimensional design information and an image of the driving part taken by the mobile terminal when abnormality occurs, and
in (b), the information for evacuating from the substrate processing apparatus is displayed based on the posture of the driving part specified in (a).

7. The work assistance method according to claim 5, wherein
the mobile terminal is a smart glass.

8. A work assistance system in occurrence of abnormality in a substrate processing apparatus performing predetermined processing on a substrate, comprising:
a plurality of substrate processing apparatuses disposed in a clean room;
a mobile terminal including an imaging part and a communication part;
a position recording part recording positions of the plurality of substrate processing apparatuses in the clean room and an evacuation position in the clean room based on a taken image obtained by taking an image of the plurality of substrate processing apparatuses by the mobile terminal; and
an abnormality processing part detecting a position of the mobile terminal based on an image taken by the mobile terminal when abnormality is detected in any of the plurality of substrate processing apparatuses, specifying an evacuation route from the position of the mobile terminal to the evacuation position, and displaying the evacuation route on the mobile terminal.

9. The work assistance system according to claim 8, wherein
the mobile terminal is a smart glass.

10. A work assistance system in occurrence of abnormality in a substrate processing apparatus performing predetermined processing on a substrate, comprising:
a substrate processing apparatus disposed in a clean room;
a mobile terminal including an imaging part and a communication part;
a storage part storing three-dimensional design information regarding at least a driving part in a processing part included in the substrate processing apparatus;
a posture specifying part specifying a posture of the driving part based on the three-dimensional design information and an image of the driving part taken by the mobile terminal when abnormality of a substrate processing apparatus is detected during a work in the substrate processing apparatus; and
an abnormality processing part displaying information for evacuating from the substrate processing apparatus on the mobile terminal based on the posture of the driving part specified by the posture specifying part.

11. The work assistance system according to claim 10, wherein
the mobile terminal is a smart glass.
